(19) United States
(12) Patent Application Publication
(10) Pub. No.: US 2025/0359444 A1
(43) Pub. Date: Nov. 20, 2025

(54) DISPLAY DEVICE

(71) Applicant: Samsung Display Co., LTD., Yongin-si (KR)

(72) Inventor: Jong Hyun CHOI, Yongin-si (KR)

(21) Appl. No.: 19/021,713

(22) Filed: Jan. 15, 2025

(30) Foreign Application Priority Data
May 16, 2024 (KR) 10-2024-0063574

(51) Int. Cl. H10K 59/131; H10K 59/121

(52) U.S. Cl. CPC H10K 59/131; H10K 59/1213

(57) ABSTRACT

A display device includes a substrate; a circuit layer; and an element layer. The circuit layer includes light-emitting pixel drivers arranged side by side in a first direction and a second direction intersecting each other; and a first signal transmission line transmitting a first signal to a first light-emitting pixel driver and a second light-emitting pixel driver, which neighbor each other in the second direction, among the light-emitting pixel drivers. The first signal transmission line includes a first main portion overlapping the first light-emitting pixel driver and extending in the first direction; a first sub-extension portion electrically connected to the first main portion and extending in the second direction; and a second sub-extension portion electrically connected to the first sub-extension portion, extending in the first direction, and overlapping the second light-emitting pixel driver.

This application claims priority to Korean Patent Application No. 10-2024-0063574, filed on May 16, 2024, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information society develops, demands for display devices for displaying images are increasing in various forms. For example, display devices are applied to various electronic devices such as smartphones, digital cameras, notebook computers. navigation devices, and smart televisions.

The display devices may be flat panel display devices such as liquid crystal display devices, field emission display devices, and light-emitting display devices. Here, the light-emitting display devices may include an organic light-emitting display device including an organic light-emitting element, an inorganic light-emitting display device including an inorganic light-emitting element such as an inorganic semiconductor, and a micro-light-emitting display device or nano-light-emitting display device including a micro-light-emitting element or nano-light-emitting element.

An organic light-emitting display device displays an image using light-emitting elements, each including a light-emitting layer of an organic light-emitting material. The organic light-emitting display device that displays an image using the self-light-emitting elements may have relatively superior performance in terms of power consumption, response speed, luminous efficiency, luminance, and wide viewing angle, compared with other display devices.

A surface of a display device may be a display surface including a display area where an image is displayed and a non-display area disposed around the display area. In the display area, emission areas that emit light with respective luminances and colors may be arranged.

### SUMMARY

The display device may include light-emitting elements disposed in the emission areas, respectively, and light-emitting pixel drivers electrically connected to the light-emitting elements, respectively. The light-emitting pixel drivers may supply driving currents to the light-emitting elements, respectively.

Each of the light-emitting pixel drivers may include a first transistor generating a driving current and a second transistor electrically connected between a data line, which transmits a data signal, and the first transistor and may further include transistors for selective electrical connection, initialization or reset of some nodes.

Therefore, it is difficult to reduce a width of each of the light-emitting pixel drivers. Accordingly, there may be a limit to increasing the resolution of the display device.

Features of the disclosure provide a display device which may be advantageously made to have relatively high resolution by reducing a width of each of light-emitting pixel drivers while maintaining transistors of each of the light-emitting pixel drivers.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, there is provided a display device including a substrate including a display area in which emission areas are arranged; a circuit layer disposed on the substrate; and an element layer disposed on the circuit layer and including light-emitting elements disposed in the emission areas, respectively. The circuit layer may include light-emitting pixel drivers electrically connected to the light-emitting elements of the element layer, respectively, and arranged side by side in a first direction and a second direction intersecting each other; and a first signal transmission line transmitting a first signal to a first light-emitting pixel driver and a second light-emitting pixel driver, which neighbor each other in the second direction, among the light-emitting pixel drivers. The first signal transmission line may include a first main portion overlapping the first light-emitting pixel driver and extending in the first direction; a first sub-extension portion electrically connected to the first main portion and extending in the second direction; and a second sub-extension portion electrically connected to the first sub-extension portion, extending in the first direction, and overlapping the second light-emitting pixel driver.

In an embodiment, the circuit layer may further include a constant voltage transmission line transmitting a constant voltage to the first light-emitting pixel driver and the second light-emitting pixel driver, The constant voltage transmission line may be next to a boundary between the first light-emitting pixel driver and the second light-emitting pixel driver and extends in the first direction, and the first sub-extension portion may intersect the constant voltage transmission line.

In an embodiment, the circuit layer may further include second signal transmission lines extending in the first direction and transmitting a second signal to the first light-emitting pixel driver and the second light-emitting pixel driver, where one of the second signal transmission lines overlaps the first light-emitting pixel driver, and a remaining one of the second signal transmission lines overlaps the second light-emitting pixel driver.

In an embodiment, the one of the second signal transmission lines may be disposed between the first main portion and the constant voltage transmission line in the second direction, the remaining one of the second signal transmission lines may be disposed between the second sub-extension portion and the constant voltage transmission line in the second direction, and the circuit layer may further include a shielding protruding portion protruding from the constant voltage transmission line in the second direction and overlapping intersection areas of the first sub-extension portion and the second signal transmission lines.

In an embodiment, each of the light-emitting pixel drivers may include a first transistor electrically connected between a first node and a second node; a pixel capacitor electrically connected between a first power line, which transmits first power, and a third node; a second transistor electrically connected between a data line, which transmits a data signal, and the first node; a third transistor electrically connected between the second node and the third node; and a fourth transistor electrically connected between a gate initialization voltage line, which transmits a gate initialization voltage, and the third node. The first node may be electrically connected to a first electrode of the first transistor, the second node may be electrically connected to a second electrode of the first transistor, the third node may be electrically connected to a gate electrode of the first transistor, the third transistor may be turned on by a scan initialization signal of a scan initialization line, the fourth transistor may be turned on by a gate control signal of a gate control line, one of the first signal transmission line and the second signal transmission lines may be the scan initialization line, the remaining one may be the gate control line, and the constant voltage transmission line may be the gate initialization voltage line.

In an embodiment, the light-emitting pixel drivers may further include a third light-emitting pixel driver neighboring the first light-emitting pixel driver in the first direction and a fourth light-emitting pixel driver neighboring the second light-emitting pixel driver in the first direction, the first signal transmission line and the constant voltage transmission line may be electrically connected to the third light-emitting pixel driver and the fourth light-emitting pixel driver, the first main portion further overlaps the third light-emitting pixel driver, the second sub-extension portion further overlaps the fourth light-emitting pixel driver, and the circuit layer may further include a second signal transmission line transmitting a second signal to the first light-emitting pixel driver, the second light-emitting pixel driver, the third light-emitting pixel driver and the fourth light-emitting pixel driver, The second signal transmission line may include a second main portion overlapping the second light-emitting pixel driver and the fourth light-emitting pixel driver and extending in the first direction; a third sub-extension portion electrically connected to the second main portion and extending in the second direction; and a fourth sub-extension portion electrically connected to the third sub-extension portion, extending in the first direction, and overlapping the first light-emitting pixel driver and the third light-emitting pixel driver. The first main portion may be disposed between the constant voltage transmission line and the fourth sub-extension portion, and the second sub-extension portion may be disposed between the constant voltage transmission line and the second main portion.

In an embodiment, the circuit layer may further include a shielding protruding portion protruding from the constant voltage transmission line in the second direction and overlapping an intersection area of the third sub-extension portion and the first main portion.

In an embodiment, each of the light-emitting pixel drivers may include a first transistor electrically connected between a first node and a second node; a pixel capacitor electrically connected between a first power line, which transmits first power, and a third node; a second transistor electrically connected between a data line, which transmits a data signal, and the first node; a third transistor electrically connected between the second node and the third node; and a fourth transistor electrically connected between a gate initialization voltage line, which transmits a gate initialization voltage, and the third node. The first node may be electrically connected to a first electrode of the first transistor, the second node may be electrically connected to a second electrode of the first transistor, the third node may be electrically connected to a gate electrode of the first transistor, the third transistor may be turned on by a scan initialization signal of a scan initialization line, the fourth transistor may be turned on by a gate control signal of a gate control line, the first signal transmission line may be the scan initialization line, the second signal transmission line may be the gate control line, and the constant voltage transmission line may be the gate initialization voltage line.

In an embodiment, each of the light-emitting pixel drivers may include a first transistor electrically connected between a first node and a second node; a second transistor electrically connected between a data line, which transmits a data signal, and a third node; a third transistor electrically connected between a reference voltage line, which transmits a gate reference voltage, and the third node; a first pixel capacitor electrically connected between the second node and the third node; a second pixel capacitor electrically connected between a first power line, which transmits first power, and the second node; a fourth transistor electrically connected between an anode initialization voltage line, which transmits an anode initialization voltage, and a fourth node; a fifth transistor electrically connected between the first power line and the first node; and a sixth transistor electrically connected between the second node and the fourth node. The first node may be electrically connected to a first electrode of the first transistor, the second node may be electrically connected to a second electrode of the first transistor, the third node may be electrically connected to a gate electrode of the first transistor, the fourth node may be electrically connected to one of the light-emitting elements, the fourth transistor may be turned on by a scan initialization signal of a scan initialization line, the fifth transistor may be turned on by a first emission control signal of a first emission control line, the sixth transistor may be turned on by a second emission control signal of a second emission control line, the first signal transmission line may be the scan initialization line, the second signal transmission line may be the second emission control line, and the constant voltage transmission line may be the anode initialization voltage line.

In an embodiment, the circuit layer may include a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first inter-insulating layer covering the second gate conductive layer; a second semiconductor layer disposed on the first inter-insulating layer; a third gate insulating layer covering the second semiconductor layer; a third gate conductive layer disposed on the third gate insulating layer; and a second inter-insulating layer covering the third gate conductive layer.

In an embodiment, the constant voltage transmission line may be disposed in one of the first gate conductive layer and the second gate conductive layer, the first sub-extension portion may be disposed in a remaining one of the first gate conductive layer and the second gate conductive layer, and the first main portion and the second sub-extension portion may be disposed in the third gate conductive layer.

In an embodiment, the constant voltage transmission line may be disposed in the second gate conductive layer, the first sub-extension portion may be disposed in one of the first gate conductive layer and the third gate conductive layer, and the first main portion and the second sub-extension portion may be disposed in the third gate conductive layer.

In an embodiment, the circuit layer further may include a first source-drain conductive layer disposed on the second inter-insulating layer, The constant voltage transmission line may be disposed in the first source-drain conductive layer, the first signal transmission line may be disposed in one of the first gate conductive layer and the second gate conductive layer, and the second signal transmission line may be disposed in the remaining one of the first gate conductive layer and the second gate conductive layer.

In another embodiment of the disclosure, there is provided a display device including a substrate including a display area in which emission areas may be arranged; a circuit layer disposed on the substrate; and an element layer disposed on the circuit layer and including light-emitting elements disposed in the emission areas, respectively. The circuit layer includes light-emitting pixel drivers electrically connected to the light-emitting elements of the element layer, respectively, and arranged side by side in a first direction and a second direction intersecting each other; a first signal transmission line transmitting a first signal to a first light-emitting pixel driver and a second light-emitting pixel driver, which neighbor each other in the second direction, among the light-emitting pixel drivers; and a constant voltage transmission line transmitting a constant voltage to the first light-emitting pixel driver and the second light-emitting pixel driver. The constant voltage transmission line is next to a boundary between the first light-emitting pixel driver and the second light-emitting pixel driver and extends in the first direction, the first signal transmission line includes a first sub-extension portion intersecting the constant voltage transmission line, and the first sub-extension portion is disposed in a different conductive layer from the constant voltage transmission line.

In an embodiment, the circuit layer may include a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first inter-insulating layer covering the second gate conductive layer; a second semiconductor layer disposed on the first inter-insulating layer; a third gate insulating layer covering the second semiconductor layer; a third gate conductive layer disposed on the third gate insulating layer; and a second inter-insulating layer covering the third gate conductive layer.

In an embodiment, the constant voltage transmission line may be disposed in one of the first gate conductive layer and the second gate conductive layer, and the first sub-extension portion may be disposed in a remaining one of the first gate conductive layer and the second gate conductive layer.

In an embodiment, the constant voltage transmission line may be disposed in the second gate conductive layer, and the first sub-extension portion may be disposed in one of the first gate conductive layer and the third gate conductive layer.

In an embodiment, the light-emitting pixel drivers may further include a third light-emitting pixel driver neighboring the first light-emitting pixel driver in the first direction and a fourth light-emitting pixel driver neighboring the second light-emitting pixel driver in the first direction, the first signal transmission line and the constant voltage transmission line may be electrically connected to the third light-emitting pixel driver and the fourth light-emitting pixel driver, and the circuit layer further may include a second signal transmission line transmitting a second signal to the first light-emitting pixel driver, the second light-emitting pixel driver, the third light-emitting pixel driver and the fourth light-emitting pixel driver and a first source-drain conductive layer disposed on the second inter-insulating layer, The constant voltage transmission line may be disposed in the first source-drain conductive layer, the first signal transmission line may be disposed in one of the first gate conductive layer and the second gate conductive layer, and the second signal transmission line may be disposed in the remaining one of the first gate conductive layer and the second gate conductive layer.

In an embodiment, the light-emitting pixel drivers may further include a third light-emitting pixel driver neighboring the first light-emitting pixel driver in the first direction and a fourth light-emitting pixel driver neighboring the second light-emitting pixel driver in the first direction, the first signal transmission line and the constant voltage transmission line may be electrically connected to the third light-emitting pixel driver and the fourth light-emitting pixel driver, and the circuit layer may further include a second signal transmission line transmitting a second signal to the first light-emitting pixel driver, the second light-emitting pixel driver, the third light-emitting pixel driver and the fourth light-emitting pixel driver, The first signal transmission line further may include a first main portion overlapping the first light-emitting pixel driver and extending in the first direction and a second sub-extension portion overlapping the second light-emitting pixel driver, the first sub-extension portion may be electrically connected between the first main portion and the second sub-extension portion, the second signal transmission line may include a third sub-extension portion intersecting the constant voltage transmission line and the first main portion, and the third sub-extension portion may be disposed in a different conductive layer from the constant voltage transmission line and the first main portion.

In an embodiment, the circuit layer may further include a shielding protruding portion protruding from the constant voltage transmission line in the second direction and overlapping an intersection area of the third sub-extension portion and the first main portion.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view of an embodiment of a display device;

FIG. 2 is a plan view of the display device of FIG. 1;

FIG. 3 is a cross-sectional view taken along line A-A′ of FIG. 2;

FIG. 4 is a plan view of part B of FIG. 2;

FIG. 5 is an equivalent circuit diagram of an embodiment of a light-emitting pixel driver of FIG. 4;

FIG. 6 is a cross-sectional view illustrating a first transistor, a second transistor, a fourth transistor, a sixth transistor, and a light-emitting element of FIG. 5;

FIGS. 7 and 8 are plan views of an embodiment of a portion of part C of FIG. 4;

FIG. 9 is a cross-sectional view taken along ling D-D′ of FIG. 8;

FIG. 10 is a cross-sectional view taken along line E-E′ of FIG. 8;

FIGS. 11 through 15 are plan views of an embodiment of a portion of part C of FIG. 4;

FIG. 16 is an equivalent circuit diagram of an embodiment of a light-emitting pixel driver of FIG. 4; and

FIG. 17 is a plan view of a portion of part C of FIG. 4 in the embodiment of FIG. 16.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it may be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device disposed “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

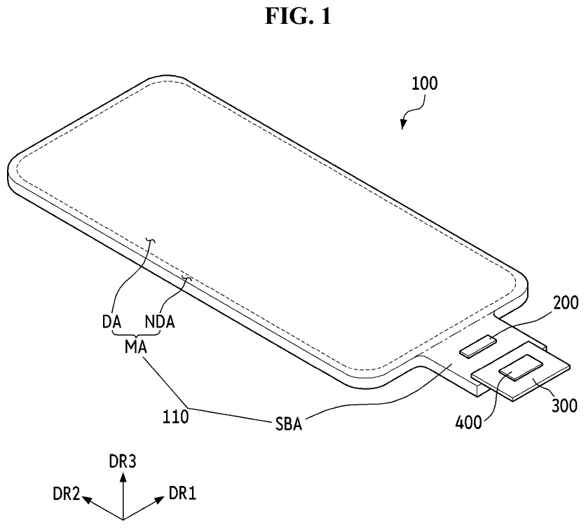

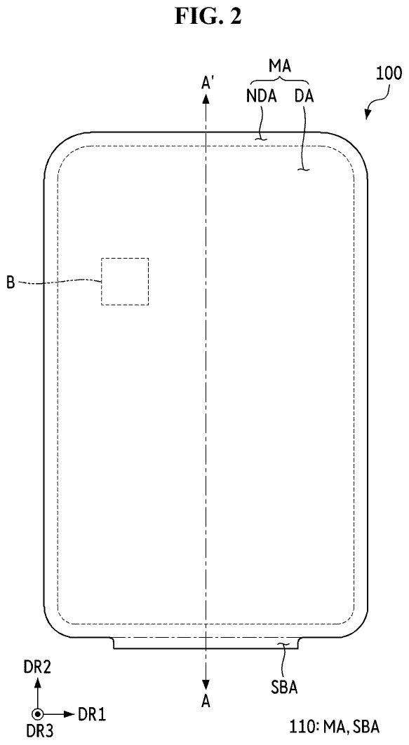

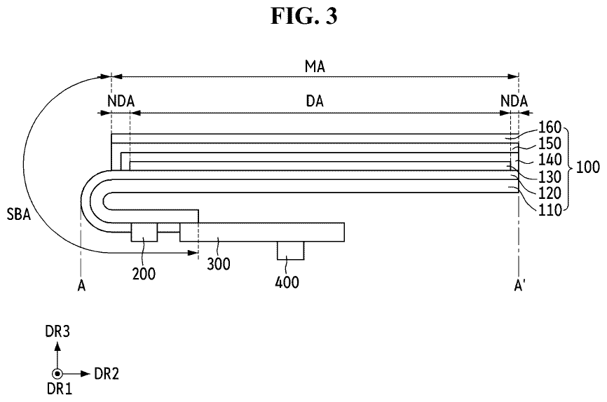

FIG. 1 is a perspective view of an embodiment of a display device 100. FIG. 2 is a plan view of the display device 100 of FIG. 1. FIG. 3 is a cross-sectional view taken along line A-A′ of FIG. 2.

Referring to FIGS. 1 and 2, the display device 100 is a device for displaying moving images or still images. The display device 100 may be used as a display screen in portable electronic devices such as mobile phones, smartphones, tablet personal computers (“PCs”), smart watches, watch phones, mobile communication terminals, electronic notebooks, electronic books, portable multimedia players (“PMPs”), navigation devices and ultra-mobile PCs (“UMPCs”), as well as in various products such as televisions, notebook computers, monitors, billboards, and Internet of things (“IoT”) devices.

The display device 100 may be a light-emitting display device such as an organic light-emitting display device using an organic light-emitting diode, a quantum dot light-emitting display device including a quantum dot light-emitting layer, an inorganic light-emitting display device including an inorganic semiconductor, or a micro- or nano-light-emitting display device using a micro-light-emitting diode or nano-light-emitting diode. A case where the display device 100 is an organic light-emitting display device will be mainly described below. However, the disclosure is not limited thereto and is also applicable to display devices including an organic insulating material, an organic light-emitting material, and a metal material.

The display device 100 may be formed flat, but the disclosure is not limited thereto. In an embodiment, the display device 100 may include a curved portion formed at left and right ends and having a constant or varying curvature, for example. In addition, the display device 100 may be flexible so that it may be curved, bent, folded, or rolled.

As illustrated in FIGS. 1 through 3, the display device 100 includes a substrate 110.

The substrate 110 may include a main area MA corresponding to a display surface of the display device 100 and a sub-area SBA protruding from a side of the main area MA.

As illustrated in FIG. 2, the main area MA may include a display area DA disposed in most of the center and a non-display area NDA disposed around the display area DA.

The display area DA may be shaped like a quadrangular plane, e.g., rectangular plane having short sides in a first direction DR1 and long sides in a second direction DR2 intersecting the first direction DR1. Each corner where a short side extending in the first direction DR1 meets a long side extending in the second direction DR2 may be rounded to have a predetermined curvature or may be right-angled. The planar shape of the display area DA is not limited to a quadrilateral shape but may also be other polygonal shapes, a circular shape, or an oval shape.

The non-display area NDA may be disposed at edges of the main area MA to surround the display area DA.

The sub-area SBA may be an area extending, in the second direction DR2, from a portion of a side of the main area MA extending in the first direction DR1.

The sub-area SBA may include a bending area that is transformed into a bent shape.

FIGS. 2 and 3 illustrate the display device 100 with a portion of the sub-area SBA bent.

As illustrated in FIG. 3, the sub-area SBA may include the bending area transformed into a bent shape, a first sub-area disposed between a side of the main area MA and a side of the bending area, and a second sub-area extending from an opposite side of the bending area.

When the bending area is transformed into a bent shape, the second sub-area may be placed on a back surface of the display device 100 and overlapped by the main area MA.

A display driving circuit 200 provided as an integrated circuit chip may be disposed (e.g., mounted) in the sub-area SB.

A circuit board 300 may be bonded to a side of the sub-area SB.

A touch driving circuit 400 provided as an integrated circuit chip may be disposed (e.g., mounted) on the circuit board 300.

Referring to FIG. 3, the display device 100 in the embodiments includes the substrate 110, a circuit layer 120 disposed on the substrate 110, and an element layer 130 disposed on the circuit layer 120.

The display device 100 in the embodiments may further include a sealing layer 140 disposed on the element layer 130 and a touch sensor layer 150 disposed on the sealing layer 140.

In addition, the display device 100 in the embodiments may further include a polarization layer 160 disposed on the touch sensor layer 150 to reduce reflection of external light.

The substrate 110 may include or consist of an insulating material such as polymer resin. In an embodiment, the substrate 110 may include or consist of polyimide, for example. The substrate 110 may be a flexible substrate that may be bent, folded, or rolled.

In an alternative embodiment, the substrate 110 may include or consist of an insulating material such as glass.

The substrate 110 may include the main area MA and the sub-area SBA. The main area MA may include the display area DA and the non-display area NDA.

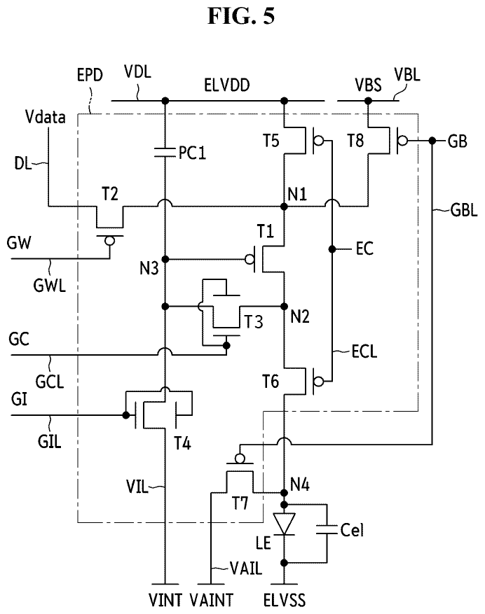

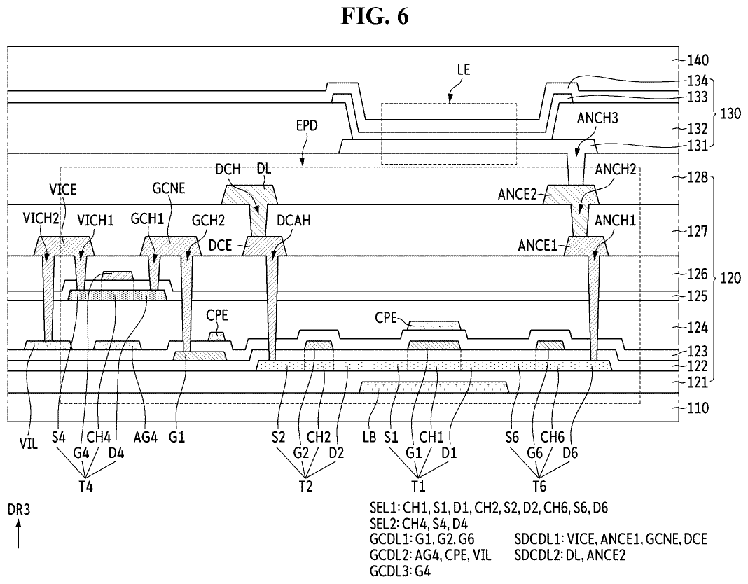

The element layer 130 may include light-emitting elements LE (refer to FIGS. 5 and 6) disposed in emission areas EA, respectively.

The circuit layer 120 may include light-emitting pixel drivers EPD electrically connected to the light-emitting elements LE of the element layer 130, respectively.

The sealing layer 140 may be disposed on the element layer 130 and may have a structure in which at least one organic layer is interposed between two or more inorganic layers.

The touch sensor layer 150 may include touch electrodes for sensing a point in the main area MA where a touch of a person or an object has occurred by detecting a signal that varies according to the touch of the person or the object.

The polarization layer 160 is designed to prevent the deterioration of the visibility of an image due to the reflection of external light by blocking the external light reflected from the touch sensor layer 150, the sealing layer 140, the element layer 130, the circuit layer 120, and their interfaces.

In embodiments, the display device 100 may further include the display driving circuit 200 provided as an integrated circuit chip and disposed (e.g., mounted) on the sub-area SBA of the substrate 110.

The display driving circuit 200 may supply data signals Vdata (refer to FIG. 5) to data lines DL (refer to FIGS. 5 and 6) of the circuit layer 120.

In embodiments, the display device 100 may further include the circuit board 300 bonded to the sub-area SBA of the substrate 110. The circuit board 300 may be bonded to pads disposed on the sub-area SBA of the substrate 110 using a low-resistance, high-reliability material such as an anisotropic conductive film or self-assembly anisotropic conductive paste (“SAP”).

The touch driving circuit 400 may be disposed (e.g., mounted) on the circuit board 300.

When the touch sensor layer 150 includes capacitive touch electrodes and sensing electrodes, the touch driving circuit 400 may detect a touch based on whether the capacitance changes. However, this is merely one of embodiments, and the touch sensor layer 150 and the touch driving circuit 400 of FIG. 3 may also be provided in a touch sensing method other than the capacitive method.

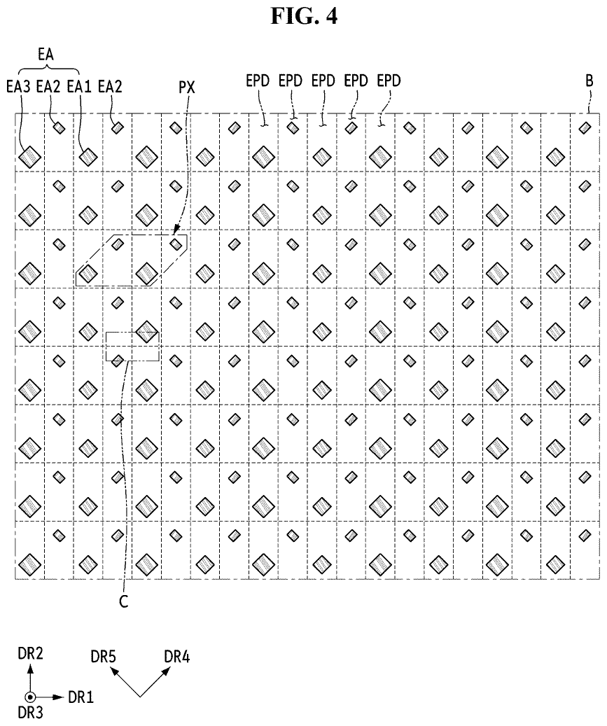

FIG. 4 is a plan view of part B of FIG. 2.

Referring to FIG. 4, the display area DA of the display device 100 in the embodiments may include emission areas EA. In addition, the display area DA may further include a non-emission area disposed between the emission areas EA.

Light-emitting pixel drivers EPD respectively corresponding to the emission areas EA may be arranged side by side in the first direction DR1 and the second direction DR2 in the display area DA. The light-emitting pixel drivers EPD may be electrically connected to the light-emitting elements LE (refer to FIGS. 5 and 6) of the element layer 130 disposed in the emission areas EA, respectively.

The emission areas EA may have a rhombic planar shape or a quadrangular planar shape, e.g., rectangular planar shape. However, this is merely one of embodiments, and the planar shape of the emission areas EA in an embodiment is not limited to that illustrated in FIG. 4. That is, the emission areas EA may also have a polygonal shape such as a quadrilateral, a pentagon or a hexagon or may have a circular or oval planar shape including curved edges.

The emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

In an embodiment, the first color may be red in a wavelength band of about 600 nanometers (nm) to about 750 nm, for example. The second color may be green in a wavelength band of about 480 nm to about 560 nm. The third color may be blue in a wavelength band of about 370 nm to about 460 nm.

The first emission areas EA1 and the third emission areas EA3 may be alternately arranged in at least one of the first direction DR1 and the second direction DR2.

The second emission areas EA2 may be arranged side by side with each other in at least one of the first direction DR1 and the second direction DR2.

In addition, the second emission areas EA2 may neighbor the first emission areas EA1 and the third emission areas EA3 in diagonal directions DR4 and DR5 intersecting the first direction DR1 and the second direction DR2.

Among these emission areas EA, the first emission areas EA1, the second emission areas EA2, and the third emission areas EA3 next (e.g., adjacent) to each other may form pixels PX which display their respective luminances and colors.

In other words, each of the pixels PX may be a basic unit that displays various colors, including white, at a predetermined luminance level.

Each of the pixels PX may include at least one first emission area EA1, at least one second emission area EA2, and at least one third emission area EA3 next (e.g., adjacent) to each other. Therefore, each of the pixels PX may display various colors through mixing of light emitted from the first through third emission areas EA1 through EA3 next (e.g., adjacent) to each other.

FIG. 5 is an equivalent circuit diagram of an embodiment of a light-emitting pixel driver EPD of FIG. 4.

Referring to FIG. 5, one of the light-emitting elements LE of the element layer 130 may be electrically connected between one of the light-emitting pixel drivers EPD of the circuit layer 120 and second power ELVSS.

That is, an anode of a light-emitting element LE may be electrically connected to a light-emitting pixel driver EPD, and the second power ELVSS having a lower voltage level than first power ELVDD may be applied to a cathode of the light-emitting element LE.

A capacitor Cel connected in parallel to the light-emitting element LE is a parasitic capacitance between the anode and the cathode.

The circuit layer 120 may further include a first power line VDL which transmits the first power ELVDD, a gate initialization voltage line VIL which transmits a gate initialization voltage VINT, an anode initialization voltage line VAIL which transmits an anode initialization voltage VAINT, and a bias power line VBL which transmits a bias voltage VBS.

The circuit layer 120 may further include a scan write line GWL which transmits a scan write signal GW, a scan initialization line GIL which transmits a scan initialization signal GI, an emission control line ECL which transmits an emission control signal EC, a gate control line GCL which transmits a gate control signal GC, and a bias control line GBL which transmits a bias control signal GB.

A light-emitting pixel driver EPD of the circuit layer 120 may include a first transistor T1 generating a driving current for driving the light-emitting element LE, two or more transistors among the second transistor T2 through the eighth transistor T8 electrically connected to the first transistor T1, and at least one pixel capacitor PC1.

The first transistor T1 may be electrically connected between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

The pixel capacitor PC1 may be electrically connected between the first power line VDL and a third node N3. The third node N3 is electrically connected to a gate electrode of the first transistor T1.

That is, the gate electrode of the first transistor T1 may be electrically connected to the first power line VDL through the pixel capacitor PC1.

Accordingly, the electric potential of the gate electrode of the first transistor T1 may be maintained using a voltage charged in the pixel capacitor PC1.

A second transistor T2 may be electrically connected between a data line DL and the first node N1.

That is, the first electrode of the first transistor T1 may be electrically connected to the data line DL through the second transistor T2.

In other words, the second transistor T2 may be electrically connected between the first electrode of the first transistor T1 and the data line DL.

The second transistor T2 may be turned on by the scan write signal GW of the scan write line GWL.

A third transistor T3 may be electrically connected between the second node N2 and the third node N3. That is, the third transistor T3 may be electrically connected between the gate electrode of the first transistor T1 and the second electrode of the first transistor T1. The third transistor T3 may be turned on by the gate control signal GC of the gate control line GCL.

A voltage difference between the second node N2 and the third node N3 may be initialized through the turned-on third transistor T3.

A fourth transistor T4 may be electrically connected between the gate initialization voltage line VIL and the third node N3. That is, the fourth transistor T4 may be connected between the gate electrode of the first transistor T1 and the gate initialization voltage line VIL. The fourth transistor T4 may be turned on by the scan initialization signal GI of the scan initialization line GIL.

The electric potential of the third node N3 may be initialized through the turned-on fourth transistor T4.

A fifth transistor T5 may be electrically connected between the first node N1 and the first power line VDL.

A sixth transistor T6 may be electrically connected between the second node N2 and a fourth node N4. The fourth node N4 is electrically connected to the anode of the light-emitting element LE.

That is, the fifth transistor T5 may be electrically connected between the first electrode of the first transistor T1 and the first power line VDL.

A sixth transistor T6 may be electrically connected between the second electrode of the first transistor T1 and the anode of the light-emitting element LE.

In other words, the first electrode (e.g., the source electrode) of the first transistor T1 may be electrically connected to the first power line VDL through the fifth transistor T5. In addition, the second electrode (e.g., the drain electrode) of the first transistor T1 may be electrically connected to the anode of the light-emitting element LE through the sixth transistor T6.

The fifth transistor T5 and the sixth transistor T6 may be turned on by the emission control signal EC of the emission control line ECL.

When a data signal Vdata of the data line DL is transmitted to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

Here, when the voltage difference between the gate electrode of the first transistor T1 and the first electrode of the first transistor T1, that is, a gate-source voltage difference is equal to or greater than a threshold voltage, the first transistor T1 may be turned on. Accordingly, a drain-source current of the first transistor T1 which corresponds to the data signal Vdata may be generated.

Then, when the fifth transistor T5 and the sixth transistor T6 are turned on, the first transistor T1 may be connected in series to the light-emitting element LE between the first power ELVDD and the second power ELVSS. Accordingly, the drain-source current of the first transistor T1 which corresponds to the data signal Vdata may be supplied as a driving current of the light-emitting element LE.

Therefore, the light-emitting element LE may emit light at a luminance level corresponding to the data signal Vdata.

A seventh transistor T7 may be electrically connected between the fourth node N4 and the anode initialization voltage line VAIL. That is, the seventh transistor T7 may be electrically connected between the anode of the light-emitting element LE and the anode initialization voltage line VAIL.

The seventh transistor T7 may be turned on by the bias control signal GB of the bias control line GBL.

The electric potential of the fourth node N4 may be initialized through the turned-on seventh transistor T7.

An eighth transistor T8 may be electrically connected between the first node N1 and the bias power line VBL. That is, the eighth transistor T8 may be electrically connected between the first electrode of the first transistor T1 and the bias power line VBL.

The eighth transistor T8 may be turned on by the bias control signal GB of the bias control line GBL.

The electric potential of the first node N1 may be initialized through the turned-on eighth transistor T8.

In embodiments, among the first through eighth transistors T1 through T8, the third transistor T3 and the fourth transistor T4 may be N-type metal-oxide-semiconductor field-effect transistors (“MOSFETs”), and the other transistors (i.e., remaining transistors), that is, the first transistor T1, the second transistor T2, the fifth transistor T5, the sixth transistor T6, the seventh transistor T7 and the eighth transistor T8 may be P-type MOSFETs.

Accordingly, in embodiments, the circuit layer 120 may include a first semiconductor layer SEL1 (refer to FIG. 6) for providing the P-type MOSFETs and a second semiconductor layer SEL2 (refer to FIG. 6) for providing the N-type MOSFETs.

The first semiconductor layer SEL1 (refer to FIG. 6) may include a channel portion, a first electrode portion, and a second electrode portion of each of the P-type MOSFETs (T1, T2, T5, T6, T7 and T8 of FIG. 5).

The second semiconductor layer SEL2 (refer to FIG. 6) may include a channel portion, a first electrode portion, and a second electrode portion of each of the N-type MOSFETs (T3 and T4 of FIG. 5).

In each transistor, the first electrode portion may be connected to a side of the channel portion, and the second electrode portion may be connected to an opposite side of the channel portion.

The first electrode portion may be a first electrode or a source electrode.

The second electrode portion may be a second electrode or a drain electrode.

FIG. 6 is a cross-sectional view illustrating the first transistor T1, the second transistor T2, the fourth transistor T4, the sixth transistor T6, and the light-emitting element LE of FIG. 5.

Referring to FIG. 6, the display device 100 in the embodiments may include the substrate 110, the circuit layer 120 on the substrate 110, and the element layer 130 on the circuit layer 120. The display device 100 may further include the sealing layer 140 on the element layer 130.

In embodiments, the circuit layer 120 may include the first semiconductor layer SEL1 (CH1, S1, D1, CH2, S2, D2, CH6, S6 and D6) disposed on the substrate 110, a first gate insulating layer 122 covering the first semiconductor layer SEL1, a first gate conductive layer GCDL1 (G1, G2 and G6) disposed on the first gate insulating layer 122, a second gate insulating layer 123 covering the first gate conductive layer GCDL1, a second gate conductive layer GCDL2 (CPE, VIL and AG4) disposed on the second gate insulating layer 123, a first inter-insulating layer 124 covering the second gate conductive layer GCDL2, the second semiconductor layer SEL2 (CH4, S4 and D4) disposed on the first inter-insulating layer 124, a third gate insulating layer 125 covering the second semiconductor layer SEL2, a third gate conductive layer GCDL3 (G4) disposed on the third gate insulating layer 125, and a second inter-insulating layer 126 covering the third gate conductive layer GCDL3.

In embodiments, the circuit layer 120 may further include a first source-drain conductive layer SDCDL1 (ANCE1 and DCE) disposed on the second inter-insulating layer 126, a first planarization layer 127 covering the first source-drain conductive layer SDCDL1, a second source-drain conductive layer SDCDL2 (DL and ANCE2) disposed on the first planarization layer 127, and a second planarization layer 128 covering the second source-drain conductive layer SDCDL2.

In embodiments, the circuit layer 120 may further include a buffer layer 121 covering the substrate 110. In this case, the first semiconductor layer SEL1 may be disposed on the buffer layer 121. The buffer layer 121 may cover a light-blocking portion LB on the substrate 110.

The light-blocking portion LB may overlap a channel portion CH1 of the first transistor T1.

As described above with reference to FIG. 5, the circuit layer 120 may include the light-emitting pixel drivers EPD which are respectively electrically connected to the light-emitting elements LE disposed in the emission areas EA and lines which transmit various signals and voltages to the light-emitting pixel drivers EPD. Each of the light-emitting pixel drivers EPD may include the first transistor T1 and two or more transistors T2 through T8 electrically connected to the first transistor T1.

The first, second, fifth, sixth, seventh and eighth transistors T1, T2, T5, T6, T7 and T8 may be provided as P-type MOSFETs, and the third and fourth transistors T3 and T4 may be provided as N-type MOSFETs.

Each of the first, second and sixth transistors T1, T2 and T6 provided as P-type MOSFETs may include a channel portion CH1, CH2 or CH6, a first electrode portion S1, S2 or S6 and a second electrode portion D1, D2 or D6 disposed in the first semiconductor layer SEL1 and a gate electrode G1, G2 or G6 overlapping the channel portion CH1, CH2 or CH6.

The gate electrodes G1, G2 and G6 of the first, second and sixth transistors T1, T2 and T6 may be disposed in the first gate conductive layer GCDL1.

The first electrode portion S1, S2 or S6 may be connected to a side of the channel portion CH1, CH2 or CH6, and the second electrode portion D1, D2 or D6 may be connected to an opposite side of the channel portion CH1, CH2 or CH6.

The first electrode portion S1, S2 or S6 and the second electrode portion D1, D2 or D6 may be doped at a higher concentration than the channel portion CH1, CH2 or CH6.

In embodiments, the fifth transistor T5 (refer to FIG. 5), the seventh transistor T7 (refer to FIG. 5), and the eighth transistor T8 (refer to FIG. 5) are provided as P-type MOSFETs which are substantially the same as the first transistor T1, the second transistor T2 and the sixth transistor T6, and thus a redundant description thereof will be omitted below.

The first electrode portion S2 of the second transistor T2 may be electrically connected to the data line DL through a data connection electrode DCE.

The data connection electrode DCE may be disposed in the first source-drain conductive layer SDCDL1 on the second inter-insulating layer 126 and may be electrically connected to the first electrode portion S2 of the second transistor T2 through a data auxiliary connecting hole DCAH. The data auxiliary connection hole DCAH may penetrate the second inter-insulating layer 126, the third gate insulating layer 125, the first inter-insulating layer 124, the second gate insulating layer 123, and the first gate insulating layer 122.

The data line DL may be disposed in the second source-drain conductive layer SDCDL2 on the first planarization layer 127 and may be electrically connected to the data connection electrode DCE through a data connection hole DCH penetrating the first planarization layer 127.

The second electrode portion D2 of the second transistor T2 may be connected to the first electrode portion S1 of the first transistor T1.

The second electrode portion D1 of the first transistor T1 may be connected to the first electrode portion S6 of the sixth transistor T6.

The second electrode portion D6 of the sixth transistor T6 may be electrically connected to an anode 131 through a first anode connection electrode ANCE1 and a second anode connection electrode ANCE2.

The first anode connection electrode ANCE1 may be disposed in the first source-drain conductive layer SDCDL1 on the second inter-insulating layer 126 and may be electrically connected to the second electrode portion D6 of the sixth transistor T6 through a first anode contact hole ANCH1.

The first anode contact hole ANCH1 may penetrate the second inter-insulating layer 126, the third gate insulating layer 125, the first inter-insulating layer 124, the second gate insulating layer 123, and the first gate insulating layer 122.

The second anode connection electrode ANCE2 may be disposed in the second source-drain conductive layer SDCDL2 on the first planarization layer 127 and may be electrically connected to the first anode connection electrode ANCE1 through a second anode contact hole ANCH2 penetrating the first planarization layer 127.

The anode 131 may be disposed on the second planarization layer 128 and may be electrically connected to the second anode connection electrode ANCE2 through a third anode contact hole ANCH3 penetrating the second planarization layer 128.

The scan write line GWL (refer to FIG. 5) electrically connected to the gate electrode G2 of the second transistor T2 and the bias control line GBL (refer to FIG. 5) electrically connected to a gate electrode of the seventh transistor T7 may be disposed in the first gate conductive layer GCDL1 on the first gate insulating layer 122.

In addition, the emission control line ECL electrically connected to a gate electrode of the fifth transistor T5 and the gate electrode G6 of the sixth transistor T6 may be disposed in the first gate conductive layer GCDL1 or the second gate conductive layer GCDL2.

In embodiments, the circuit layer 120 may further include a capacitor electrode CPE overlapping the gate electrode G1 of the first transistor T1.

The capacitor electrode CPE may be disposed in the second gate conductive layer GCDL2 on the second gate insulating layer 123.

The capacitor electrode CPE may be electrically connected to the first power line VDL (refer to FIG. 5).

Therefore, the pixel capacitor PC1 (refer to FIG. 5) between the gate electrode G1 of the first transistor T1 and the first power line VDL (refer to FIG. 5) may be provided by an overlap area between the gate electrode G1 of the first transistor T1 and the capacitor electrode CPE.

In embodiments, each of the third transistor T3 (refer to FIG. 5) and the fourth transistor T4 provided as N-type MOSFETs may include an auxiliary gate electrode AG4 disposed in the second gate conductive layer GCDL2 on the second gate insulating layer 123, a channel portion CH4, a first electrode portion S4 and a second electrode portion D4 disposed in the second semiconductor layer SEL2 on the first inter-insulating layer 124, and a gate electrode G4 disposed in the third gate conductive layer GCDL3 on the third gate insulating layer 125 and overlapping the channel portion CH4.

The third gate conductive layer GCDL3 may further include the gate control line GCL (refer to FIG. 5) electrically connected to a gate electrode of the third transistor T3 and the scan initialization line GIL (refer to FIG. 5) electrically connected to the gate electrode G4 of the fourth transistor T4.

In embodiments, the third transistor T3 is provided as an N-type MOSFET which is substantially the same as the fourth transistor T4, and thus a redundant description thereof will be omitted below.

The first electrode portion S4 of the fourth transistor T4 may be electrically connected to the gate initialization voltage line VIL through an initialization voltage connection electrode VICE.

The initialization voltage connection electrode VICE may be disposed in the first source-drain conductive layer SDCDL1 on the second inter-insulating layer 126.

The initialization voltage connection electrode VICE may be electrically connected to the first electrode portion S4 of the fourth transistor T4 through a first initialization voltage connection hole VICH1 and may be electrically connected to the gate initialization voltage line VIL through a second initialization voltage connection hole VICH2.

The second electrode portion D4 of the fourth transistor T4 may be electrically connected to the gate electrode G1 of the first transistor T1 through a gate connection electrode GCNE.

The gate connection electrode GCNE may be disposed in the first source-drain conductive layer SDCDL1 on the second inter-insulating layer 126.

The gate connection electrode GCNE may be electrically connected to the second electrode portion D4 of the fourth transistor T4 through a first gate connection hole GCH1 and may be electrically connected to the gate electrode G1 of the first transistor T1 through a second gate connection hole GCH2.

The element layer 130 may be disposed on the circuit layer 120 and may include the light-emitting elements LE corresponding to the emission areas EA, respectively.

Each of the light-emitting elements LE may include an anode 131 and a cathode 134 facing each other, and a light-emitting layer 133 disposed between them.

That is, the element layer 130 may include anodes 131 respectively disposed in the emission areas EA, a pixel defining layer 132 disposed in the non-emission area and covering edges of the anodes 131, light-emitting layers 133 respectively disposed on the anodes 131, and the cathode 134 disposed on the light-emitting layers 133 and the pixel defining layer 132.

In an alternative embodiment, each of the light-emitting elements LE may further include a first common layer disposed between the anode 131 and the light-emitting layer 133 and a second common layer disposed between the light-emitting layer 133 and the cathode 134.

The anode 131 may be disposed in each of the emission areas EA and may be electrically connected to a light-emitting pixel driver EPD of the circuit layer 120. The anode 131 may be also referred to as a pixel electrode.

The anode 131 may be electrically connected to the second anode connection electrode ANCE2 through the third anode contact hole ANCH3 penetrating the second planarization layer 128.

The light-emitting layer 133 may include an organic light-emitting material that converts electron-hole pairs into light.

The cathode 134 may be disposed in the display area DA including the emission areas EA. The second power ELVSS (refer to FIG. 5) may be commonly applied to the cathode 134. The cathode 134 may be also referred to as a common electrode.

The sealing layer 140 may be disposed on the circuit layer 120 and may cover the element layer 130.

In an embodiment, the sealing layer 140 may include a first sealing layer disposed on the element layer 130 and including or consisting of an inorganic insulating material, a second sealing layer disposed on the first sealing layer, overlapping the element layer 130 and including or consisting of an organic insulating material, and a third sealing layer disposed on the first sealing layer, covering the second sealing layer and including or consisting of an inorganic insulating material.

In embodiments, each of the light-emitting pixel drivers EPD includes the first through eighth transistors T1 through T8 and overlaps lines electrically connected to the transistors T1 through T8. Therefore, there may be a limit to reducing the width of each of the light-emitting pixel drivers EPD. Accordingly, there may be a limit to increasing the resolution of the display device 100.

To solve this problem, the following embodiments provide a display device 100 which may reduce the number of lines disposed in the display area DA while maintaining the number of transistors T1 through T8 of each of the light-emitting pixel drivers EPD.

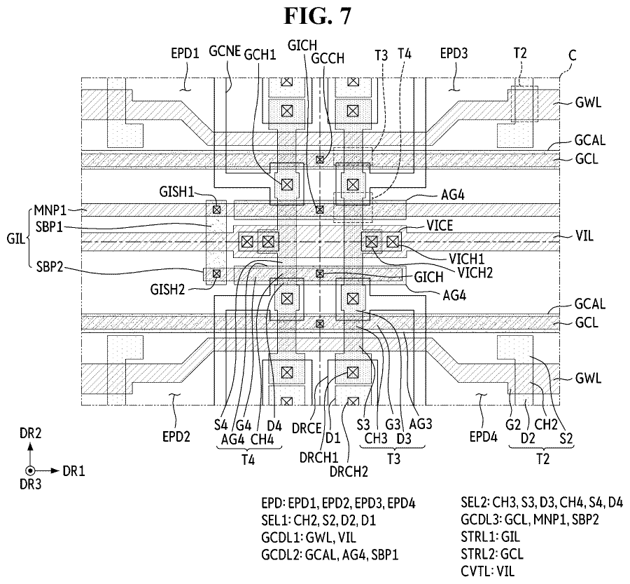

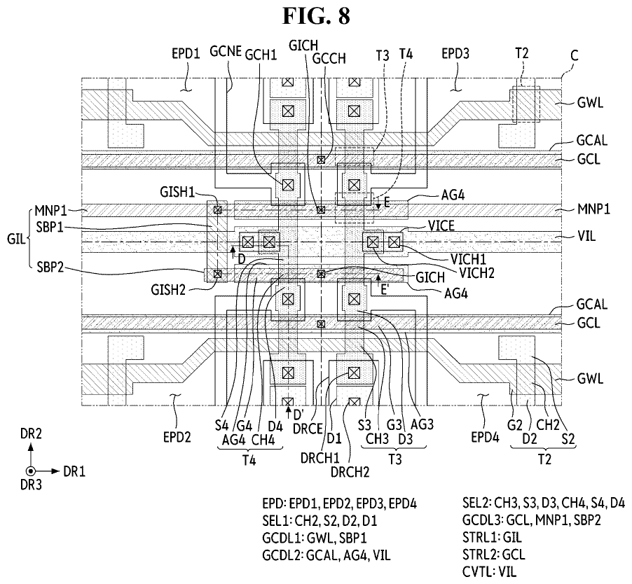

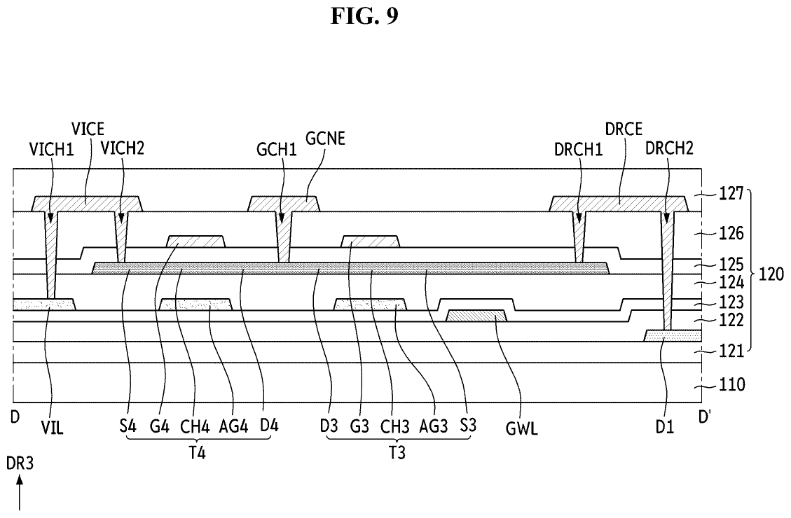

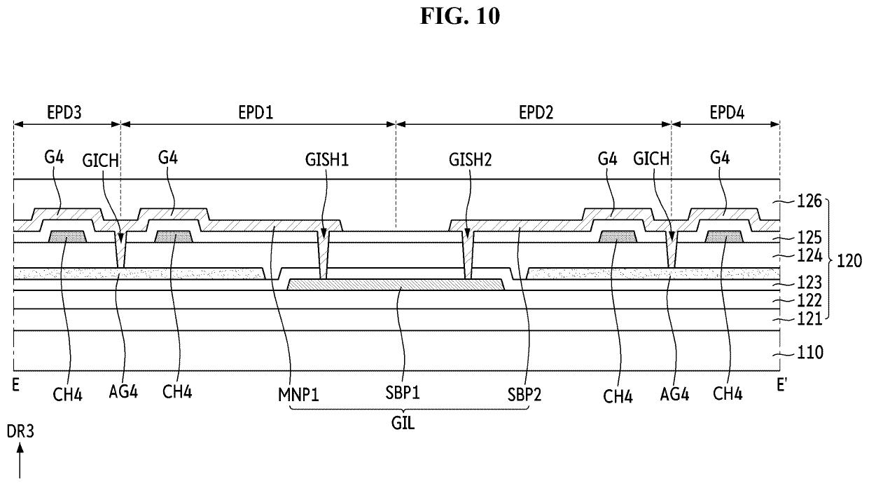

FIGS. 7 and 8 are plan views of an embodiment of a portion of part C of FIG. 4. FIG. 9 is a cross-sectional view taken along ling D-D′ of FIG. 8. FIG. 10 is a cross-sectional view taken along line E-E′ of FIG. 8.

Referring to FIGS. 7 and 8, a circuit layer 120 (refer to FIGS. 3 and 6) of a display device 100 in embodiments may include light-emitting pixel drivers EPD which are respectively electrically connected to light-emitting elements LE (refer to FIG. 6) and arranged side by side in the first direction DR1 and the second direction DR2 intersecting each other and a first signal transmission line STRL1 which transmits a first signal to a first light-emitting pixel driver EPD1 and a second light-emitting pixel driver EPD2 neighboring each other in the second direction DR2 among the light-emitting pixel drivers EPD.

The first signal transmission line STRL1 may include a first main portion MNP1 overlapping the first light-emitting pixel driver EPD1 and extending in the first direction DR1, a first sub-extension portion SBP1 electrically connected to the first main portion MNP1 and extending in the second direction DR2 toward the second light-emitting pixel driver EPD2, and a second sub-extension portion SBP2 electrically connected to the first sub-extension portion SBP1 and overlapping the second light-emitting pixel driver EPD2.

In embodiments, the circuit layer 120 may further include a constant voltage transmission line CVTL which transmits a constant voltage to the first light-emitting pixel driver EPD1 and the second light-emitting pixel driver EPD2.

The constant voltage transmission line CVTL may be disposed next (or adjacent) to a boundary between the first light-emitting pixel driver EPD1 and the second light-emitting pixel driver EPD2 and may extend in the first direction DR1.

In embodiments, the circuit layer 120 may further include second signal transmission lines STRL2 which transmit a second signal to the first light-emitting pixel driver EPD1 and the second light-emitting pixel driver EPD2.

In embodiments, the light-emitting pixel drivers EPD of the circuit layer 120 may include a third light-emitting pixel driver EPD3 neighboring the first light-emitting pixel driver EPD1 in the first direction DR1 and a fourth light-emitting pixel driver EPD4 neighboring the second light-emitting pixel driver EPD2 in the first direction DR1.

The first main portion MNP1 may further overlap the third light-emitting pixel driver EPD3. The first main portion MNP1 may extend in the first direction DR1 to further overlap other light-emitting pixel drivers disposed side by side with the first light-emitting pixel driver EPD1 and the third light-emitting pixel driver EPD3.

The second sub-extension portion SBP2 may further overlap the fourth light-emitting pixel driver EPD4.

One of the second signal transmission lines STRL2 may overlap the first light-emitting pixel driver EPD1 and the third light-emitting pixel driver EPD3.

The other (i.e., a remaining one) of the second signal transmission lines STRL2 may overlap the second light-emitting pixel driver EPD2 and the fourth light-emitting pixel driver EPD4.

The constant voltage transmission line CVTL may overlap the boundary between the first light-emitting pixel driver EPD1 and the second light-emitting pixel driver EPD2.

The first signal transmission line STRL1 and the second signal transmission lines STRL2 may be disposed next (e.g., adjacent) to the constant voltage transmission line CVTL.

In embodiments, the first main portion MNP1 of the first signal transmission line STRL1 may be disposed between a second signal transmission line STR2, which overlaps the first light-emitting pixel driver EPD1, and the constant voltage transmission line CVTL.

In addition, the second sub-extension portion SBP2 of the first signal transmission line STRL1 may be disposed between another second signal transmission line STRL2, which overlaps the second light-emitting pixel driver EPD2, and the constant voltage transmission line CVTL.

In embodiments, the first sub-extension portion SBP1 of the first signal transmission line STRL1 may extend in the second direction DR2 to intersect the constant voltage transmission line CVTL.

Accordingly, the first sub-extension portion SBP1 may be disposed in a different conductive layer from the constant voltage transmission line CVTL.

In an embodiment, as illustrated in FIG. 7, the constant voltage transmission line CVTL (VIL) may be disposed in a first gate conductive layer GCDL1, and the first sub-extension portion SBP1 may be disposed in a second gate conductive layer GCDL2.

In an alternative embodiment, in an embodiment, as illustrated in FIG. 8, the constant voltage transmission line CVTL (VIL) may be disposed in the second gate conductive layer GCDL2, and the first sub-extension portion SBP1 may be disposed in the first gate conductive layer GCDL1.

The first main portion MNP1, the second sub-extension portion SBP2, and the second signal transmission lines STRL2 may be disposed in a third gate conductive layer GCDL3.

As described above, in embodiments, the first signal transmission line STRL1 may include the first main portion MNP1 overlapping the first light-emitting pixel driver EPD1 and extending in the first direction DR1, the second sub-extension portion SBP2 overlapping the second light-emitting pixel driver EPD2, and the first sub-extension portion SBP1 electrically connecting the first main portion MNP1 and the second sub-extension portion SBP2.

Therefore, the first signal transmission line STRL1 may correspond not only to one pixel row composed of light-emitting pixel drivers EPD arranged side by side with the first light-emitting pixel driver EPD1 in the first direction DR1, but also to another pixel row composed of light-emitting pixel drivers EPD arranged side by side with the second light-emitting pixel driver EPD2 in the first direction DR1. That is, the first signal transmission line STRL1 may transmit the first signal to two adjacent pixel rows (e.g., two pixel rows immediately next to each other). Therefore, the number of first signal transmission lines STRL1 disposed in the display area DA may be reduced to half of the total number of pixel rows disposed in the display area DA. Since the number of light-emitting pixel drivers EPD disposed in the display area DA may be increased by the number of first signal transmission lines STRL1 reduced, it may be advantageous for making the display device 100 have relatively high resolution.

In embodiments, as illustrated in FIGS. 7 and 8, the first signal transmission line STRL1 which transmits the first signal may be a scan initialization line GIL which transmits a scan initialization signal GI (refer to FIG. 5).

Each of the second signal transmission lines STRL2 which transmit the second signal may be a gate control line GCL which transmits a gate control signal GC (refer to FIG. 5).

The constant voltage transmission line CVTL may be a gate initialization voltage line VIL which transmits a gate initialization voltage VINT (refer to FIG. 5).

In embodiments, as illustrated in FIGS. 7 and 8, a second transistor T2 may be disposed in an intersection area of a scan write line GWL and a first semiconductor layer SEL1.

A third transistor T3 may be disposed in an intersection area of the gate control line GCL and a second semiconductor layer SEL2.

A fourth transistor T4 may be disposed in an intersection area of the scan initialization line GIL and the second semiconductor layer SEL2.

As illustrated in FIGS. 8 and 9, the second transistor T2 may include a gate electrode G2 provided as a part of the scan write line GWL, a channel portion CH2 provided as a part of the first semiconductor layer SEL1 overlapping the gate electrode G2, a first electrode portion S2 provided as another part of the first semiconductor layer SEL1 connected to a side of the channel portion CH2, and a second electrode portion D2 provided as another part of the first semiconductor layer SEL1 connected to an opposite side of the channel portion CH2.

The scan write line GWL may be disposed in the first gate conductive layer GCDL1.

The third transistor T3 may include an auxiliary gate electrode AG3 provided as a part of a gate control auxiliary line GCAL, a gate electrode G3 provided as a part of the gate control line GCL, a channel portion CH3 provided as a part of the second semiconductor layer SEL2 overlapping the auxiliary gate electrode AG3 and the gate electrode G3, a first electrode portion S3 provided as another part of the second semiconductor layer SEL2 connected to a side of the channel portion CH3, and a second electrode portion D3 provided as another part of the second semiconductor layer SEL2 connected to an opposite side of the channel portion CH3.

The gate control auxiliary line GCAL may be disposed in the second gate conductive layer GCDL2.

The gate control line GCL may be disposed in the third gate conductive layer GCDL3.

The gate control line GCL may be electrically connected to the gate control auxiliary line GCAL through a gate control connection hole GCCH.

The first electrode portion S3 of the third transistor T3 may be electrically connected to a second electrode portion D1 of a first transistor T1 through a drain connection electrode DRCE.

The drain connection electrode DRCE may be disposed in a first source-drain conductive layer SDCDL1 (refer to FIG. 6) on a second inter-insulating layer 126.

The drain connection electrode DRCE may be electrically connected to the first electrode portion S3 of the third transistor T3 through a first drain connection hole DRCH1 and may be electrically connected to the second electrode portion D1 of the first transistor T1 through a second drain connection hole DRCH2.

The fourth transistor T4 may include an auxiliary gate electrode AG4 disposed in the second gate conductive layer GCDL2, a gate electrode G4 provided as a part of the scan initialization line GIL, a channel portion CH4 provided as a part of the second semiconductor layer SEL2 overlapping the auxiliary gate electrode AG4 and the gate electrode G4, a first electrode portion S4 provided as another part of the second semiconductor layer SEL2 connected to a side of the channel portion CH4, and a second electrode portion D4 provided as another part of the second semiconductor layer SEL2 connected to an opposite side of the channel portion CH4.

The scan initialization line GIL may be the first signal transmission line STRL1 including the first main portion MNP1, the first sub-extension portion SBP1, and the second sub-extension portion SBP2.

The first main portion MNP1 and the second sub-extension portion SBP2 may be disposed in the third gate conductive layer GCDL3.

The first sub-extension portion SBP1 may be disposed in the second gate conductive layer GCDL2.

The scan initialization line GIL may be electrically connected to the auxiliary gate electrode AG4 of the fourth transistor T4 through a scan initialization connection hole GICH.

The first electrode portion S4 of the fourth transistor T4 may be electrically connected to the gate initialization voltage line VIL through an initialization voltage connection electrode VICE.

The gate initialization voltage line VIL may be the constant voltage transmission line CVTL overlapping the boundary between the first light-emitting pixel driver EPD1 and the second light-emitting pixel driver EPD2.

The second electrode portion D4 of the fourth transistor T4 may be connected to the second electrode portion D3 of the third transistor T3 and may be electrically connected to a gate electrode G1 (refer to FIG. 6) of the first transistor T1 (refer to FIG. 6) through a gate connection electrode GCNE.

The gate connection electrode GCNE may be electrically connected to the second electrode portion D3 of the third transistor T3 and the second electrode portion D4 of the fourth transistor T4 through a first gate connection hole GCH1.

As illustrated in FIGS. 8 and 10, when the first signal transmission line STRL1 is the scan initialization line GIL, the first sub-extension portion SBP1 may be electrically connected to the first main portion MNP1 through a first initialization auxiliary connection hole GISH1 and may be electrically connected to the second sub-extension portion SBP2 through a second initialization auxiliary connection hole GISH2.

The first main portion MNP1 may overlap the first light-emitting pixel driver EPD1 and the third light-emitting pixel driver EPD3.

The second sub-extension portion SBP2 may overlap the second light-emitting pixel driver EPD2 and the fourth light-emitting pixel driver EPD4.

FIG. 7 illustrates, in an embodiment, a case where the constant voltage transmission line CVTL is disposed in the first gate conductive layer GCDL1, and the first sub-extension portion SBP1 of the first signal transmission line STRL1 is disposed in the second gate conductive layer GCDL2. In addition, FIG. 8 illustrates, in another embodiment, a case where the constant voltage transmission line CVTL is disposed in the second gate conductive layer GCDL2, and the first sub-extension portion SBP1 of the first signal transmission line STRL1 is disposed in the first gate conductive layer GCDL1. However, these are merely illustrative embodiments, and the arrangement form of the first sub-extension portion SBP1 and the constant voltage transmission line CVTL may be variously changed as long as the first sub-extension portion SBP1 and the constant voltage transmission line CVTL are disposed in different gate conductive layers.

That is, the constant voltage transmission line CVTL may be disposed in one of the first gate conductive layer GCDL1 and the second gate conductive layer GCDL2, and the first sub-extension portion SBP1 may be disposed in the other (i.e., a remaining one) of the first gate conductive layer GCDL1 and the second gate conductive layer GCDL2.

In an alternative embodiment, the constant voltage transmission line CVTL may be disposed in the second gate conductive layer GCDL2, and the first sub-extension portion SBP1 may be disposed in one of the first gate conductive layer GCDL1 and the third gate conductive layer GCDL3.

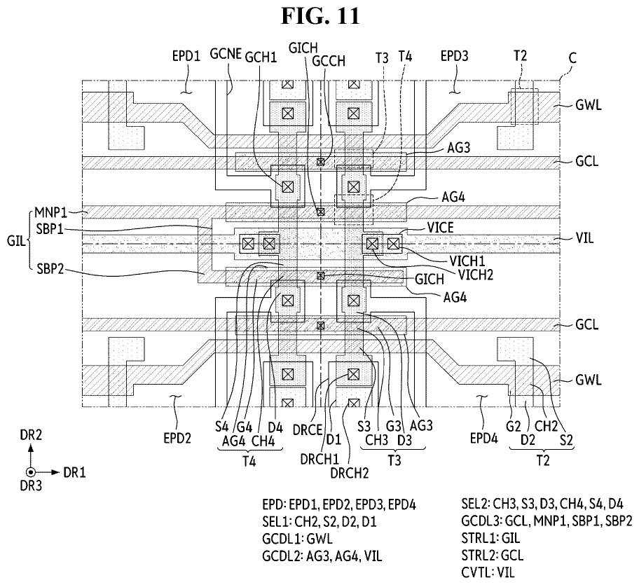

FIGS. 11 through 15 are plan views of an embodiment of a portion of part C of FIG. 4.

A display device 100 of an embodiment illustrated in FIG. 11 is substantially the same as the display device 100 of the embodiment illustrated in FIG. 8 except that a first sub-extension portion SBP1 of a first signal transmission line STRL1 is disposed in a third gate conductive layer GCDL3 and that an auxiliary gate electrode AG3 of a third transistor T3 is electrically connected to a gate control line GCL instead of a gate control auxiliary line (also referred to as a gate control auxiliary wire) GCAL. Therefore, any redundant description will be omitted below.

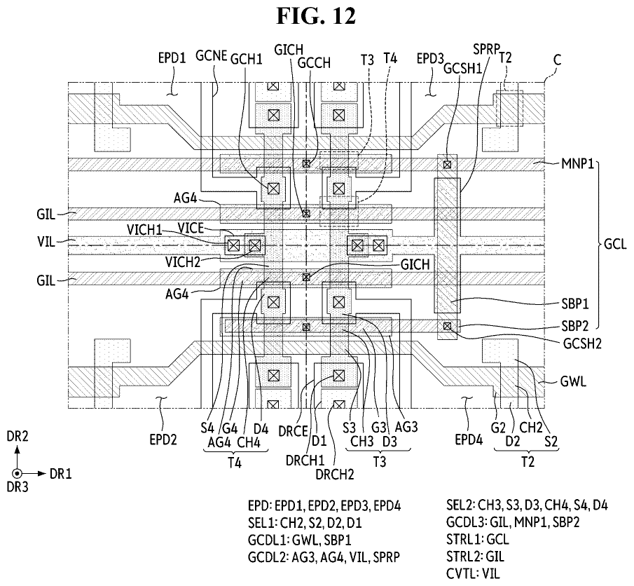

A display device 100 of an embodiment illustrated in FIG. 12 is substantially the same as the display device 100 of the embodiment illustrated in FIG. 8 except that a first signal transmission line STRL1 is a gate control line GCL and second signal transmission lines STRL2 are scan initialization lines GIL and that a circuit layer 120 further includes a shielding protruding portion SPRP. Therefore, any redundant description will be omitted below.

As illustrated in FIG. 12, in an embodiment, one second signal transmission line STRL2 overlapping a first light-emitting pixel driver EPD1 may be disposed between a first main portion MNP1 of the first signal transmission line STRL1 and a constant voltage transmission line CVTL in the second direction DR2.

In addition, another second signal transmission line STRL2 overlapping a second light-emitting pixel driver EPD2 may be disposed between a second sub-extension portion SBP2 of the first signal transmission line STRL1 and the constant voltage transmission line CVTL in the second direction DR2.

In this case, a first sub-extension portion SBP1 of the first signal transmission line STRL1 may intersect not only the constant voltage transmission line CVTL, but also the one second signal transmission line STRL2 and the another second signal transmission line STRL2.

In an embodiment, the circuit layer 120 may further include the shielding protruding portion SPRP protruding from the constant voltage transmission line CVTL (VIL) in the second direction DR2 and overlapping intersection areas of the first sub-extension portion SBP1 and the second signal transmission lines STRL2.

The shielding protruding portion SPRP may be disposed in a second gate conductive layer GCDL2 together with the constant voltage transmission line CVTL, the first sub-extension portion SBP1 may be disposed in a first gate conductive layer GCDL1, and the second signal transmission lines STRL2 may be disposed in a third gate conductive layer GCDL3.

Accordingly, the shielding protruding portion SPRP whose electric potential is maintained on a constant voltage of the constant voltage transmission line CVTL may be interposed between the first sub-extension portion SBP1 and the second signal transmission lines STRL2. Therefore, the coupling failure between a first signal of the first sub-extension portion SBP1 and a second signal of the second signal transmission lines STRL2 may be reduced.

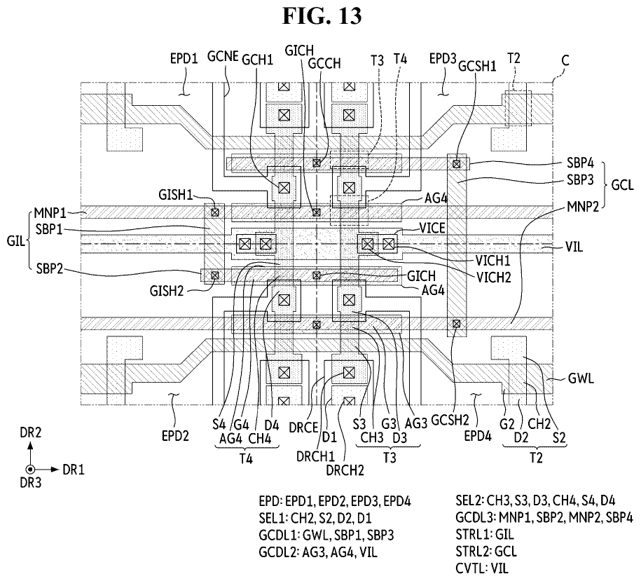

A display device 100 of an embodiment illustrated in FIG. 13 is substantially the same as the display device 100 of the embodiment illustrated in FIG. 8 except that a circuit layer 120 includes a second signal transmission line STRL2 which transmits a second signal to a first light-emitting pixel driver EPD1, a second light-emitting pixel driver EPD2, a third light-emitting pixel driver EPD3, and a fourth light-emitting pixel driver EPD4. Therefore, any redundant description will be omitted below.

As illustrated in FIG. 13, in an embodiment, the second signal transmission line STRL2 may include a second main portion MNP2 overlapping the second light-emitting pixel driver EPD2 and the fourth light-emitting pixel driver EPD4 and extending in the first direction DR1, a third sub-extension portion SBP3 electrically connected to the second main portion MNP2 and extending in the second direction DR2, and a fourth sub-extension portion SBP4 electrically connected to the third sub-extension portion SBP3 and overlapping the first light-emitting pixel driver EPD1 and the third light-emitting pixel driver EPD3.

A first main portion MNP1 of a first signal transmission line STRL1 may be disposed between a constant voltage transmission line CVTL and the fourth sub-extension portion SBP4 of the second signal transmission line STRL2 in the second direction DR2.

A second sub-extension portion SBP2 of the first signal transmission line STRL1 may be disposed between the constant voltage transmission line CVTL and the second main portion MNP4 of the second signal transmission line STRL2 in the second direction DR2.

A first sub-extension portion SBP1 of the first signal transmission line STRL1 may overlap the first light-emitting pixel driver EPD1 and the second light-emitting pixel driver EPD2.

The third sub-extension portion SBP3 of the second signal transmission line STRL2 may overlap the third light-emitting pixel driver EPD3 and the fourth light-emitting pixel driver EPD4.

The third sub-extension portion SBP3 may intersect the constant voltage transmission line CVTL and the first main portion MNP1.

The third sub-extension portion SBP3 may be disposed in a first gate conductive layer GCDL1.

The second main portion MNP2 and the fourth sub-extension portion SBP4 may be disposed in a third gate conductive layer GCDL3.

In this case, not only the number of first signal transmission lines STRL1 disposed in the display area DA, but also the number of second signal transmission lines STRL2 disposed in the display area DA may be reduced to half of the total number of pixel rows disposed in the display area DA. Since the number of light-emitting pixel drivers EPD disposed in the display area DA may be further increased by the number of first signal transmission lines STRL1 reduced and the number of second signal transmission lines STRL2 reduced, it may be more advantageous for making the display device 100 have relatively high resolution.

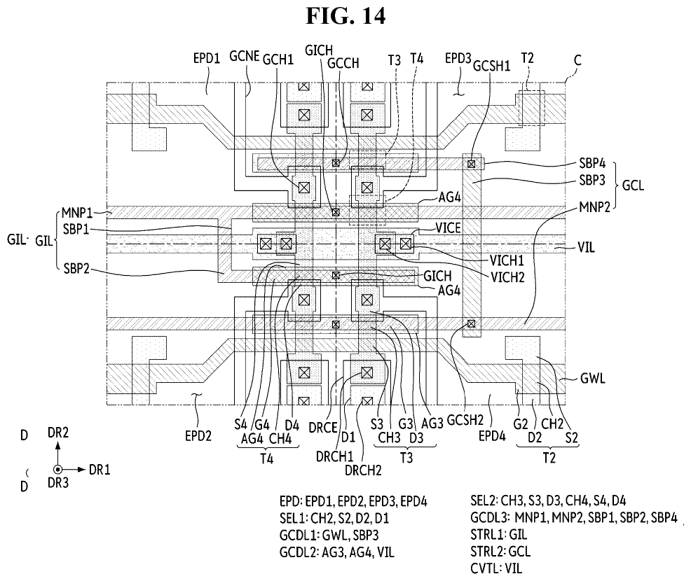

A display device 100 of an embodiment illustrated in FIG. 14 is substantially the same as the display device 100 of the embodiment illustrated in FIG. 13 except that a first sub-extension portion SBP1 is disposed in a third gate conductive layer GCDL3, but a third sub-extension portion SBP3 is disposed in a first gate conductive layer GCDL1. Therefore, any redundant description will be omitted below.

In this case, since connection holes for electrical connection between a first main portion MNP1 and a second sub-extension portion SBP2 and the first sub-extension portion SBP1 may be removed, it may be more advantageous for making the display device 100 have relatively high resolution.

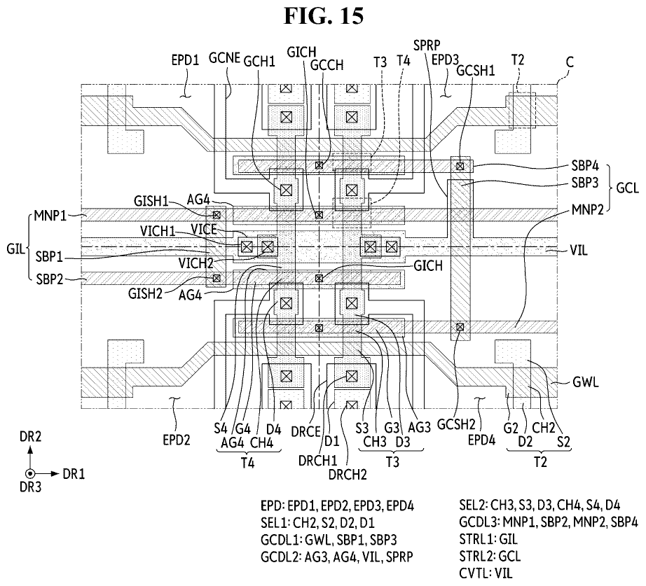

A display device 100 of an embodiment illustrated in FIG. 15 is substantially the same as the display device 100 of the embodiment illustrated in FIG. 13 except that a circuit layer 120 further includes a shielding protruding portion SPRP. Therefore, any redundant description will be omitted below.

In an embodiment, the circuit layer 120 may further include the shielding protruding portion SPRP protruding from a constant voltage transmission line CVTL (VIL) in the second direction DR2 and overlapping an intersection area of a third sub-extension portion SBP3 and a first main portion MNP1.

The shielding protruding portion SPRP may be disposed in a second gate conductive layer GCDL2 together with the constant voltage transmission line CVTL, the third sub-extension portion SBP3 may be disposed in a first gate conductive layer GCDL1, and the first main portion MNP1 may be disposed in a third gate conductive layer GCDL3.

Accordingly, the shielding protruding portion SPRP whose electric potential is maintained on a constant voltage of the constant voltage transmission line CVTL may be interposed between the third sub-extension portion SBP3 and the first main portion MNP1. Therefore, the coupling failure between a first signal of the first main portion MNP1 and a second signal of the third sub-extension portion SBP3 may be reduced.

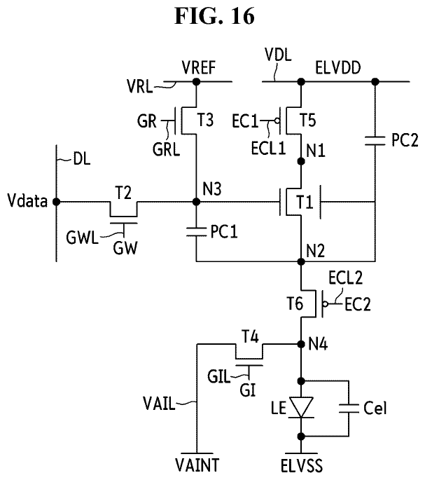

FIG. 16 is an equivalent circuit diagram of an embodiment of a light-emitting pixel driver of FIG. 4.

Referring to FIG. 16, each of light-emitting pixel drivers EPD of a display device 100 in an embodiment may include first through fourth transistors T1 through T4 provided as N-type MOSFETs, and fifth and sixth transistors T5 and T6 provided as P-type MOSFETs.

The first transistor T1 may be electrically connected between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

In other words, the first electrode (e.g., the source electrode) of the first transistor T1 may be electrically connected to a first power line VDL through the fifth transistor T5. In addition, the second electrode (e.g., the drain electrode) of the first transistor T1 may be electrically connected to an anode of a light-emitting element LE through the sixth transistor T6.

The second transistor T2 may be electrically connected between a data line DL and a third node N3. The third node N3 is electrically connected to a gate electrode of the first transistor T1.

The second transistor T2 may be turned on by a scan write signal GW of a scan write line GWL.

When the second transistor T2 is turned on, a data signal Vdata of the data line DL may be transmitted to the third node N3.

A first pixel capacitor PC1 may be electrically connected between the second node N2 and the third node N3.

A potential difference between the second node N2 and the third node N3 may be maintained by the first pixel capacitor PC1 for a predetermined period of time.

The third transistor T3 may be electrically connected between a reference voltage line VRL, which transmits a gate reference voltage VREF, and the third node N3.

The third transistor T3 may be turned on by a reset control signal GR of a reset control line GRL.

When the third transistor T3 is turned on, the electric potential of the third node N3 may be adjusted to the gate reference voltage VREF.

A second pixel capacitor PC2 may be electrically connected between the first power line VDL, which transmits first power ELVDD, and the second node N2.

The electric potential of the second node N2 may be maintained by the second pixel capacitor PC2.

The fourth transistor T4 may be electrically connected between an anode initialization voltage line VAIL, which transmits an anode initialization voltage VAINT, and a fourth node N4. The fourth node N4 is electrically connected to the anode of the light-emitting element LE.

The fourth transistor T4 may be turned on by a scan initialization signal GI of a scan initialization line GIL.

When the fourth transistor T4 is turned on, the electric potential of the fourth node N4 may be initialized to the anode initialization voltage VAINT of the anode initialization voltage line VAIL.

The fifth transistor T5 may be electrically connected between the first power line VDL and the first node N1.

The fifth transistor T5 may be turned on by a first emission control signal EC1 of a first emission control line ECL1.

When the fifth transistor T5 is turned on, the first power ELVDD may be transmitted to the first node N1.

The sixth transistor T6 may be electrically connected between the second node N2 and the fourth node N4.

The sixth transistor T6 may be turned on by a second emission control signal EC2 of a second emission control line ECL2.

When the sixth transistor T6 is turned on, a source-drain current of the first transistor T1 generated in a size corresponding to the data signal Vdata may be supplied as a driving current of the light-emitting element LE.

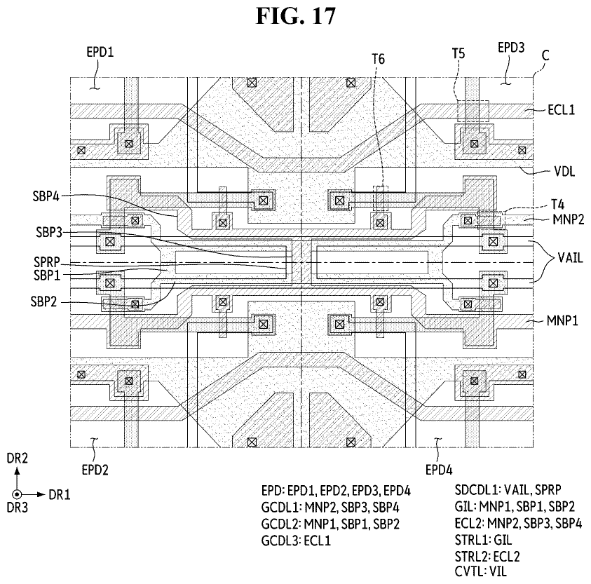

FIG. 17 is a plan view of a portion of part C of FIG. 4 in the embodiment of FIG. 16.

Referring to FIG. 17, a circuit layer 120 (refer to FIG. 3) of a display device 100 in an embodiment may include a first signal transmission line STRL1 which transmits a first signal to a first light-emitting pixel driver EPD1, a second light-emitting pixel driver EPD2, a third light-emitting pixel driver EPD3 and a fourth light-emitting pixel driver EPD4, a constant voltage transmission line CVTL which transmits a constant voltage to the first light-emitting pixel driver EPD1 and the second light-emitting pixel driver EPD2, and a second signal transmission line STRL2 which transmits a second signal to the first light-emitting pixel driver EPD1, the second light-emitting pixel driver EPD2, the third light-emitting pixel driver EPD3 and the fourth light-emitting pixel driver EPD4.

The first signal transmission line STRL1 which transmits the first signal may be the scan initialization line GIL which transmits the scan initialization signal GI (refer to FIG. 16).

The first signal transmission line STRL1 may include a first main portion MNP1 overlapping the first light-emitting pixel driver EPD1 and the third light-emitting pixel driver EPD3 and extending in the first direction DR1, a first sub-extension portion SBP1 electrically connected to the first main portion MNP1 and extending in the second direction DR2, and a second sub-extension portion SBP2 electrically connected to the first sub-extension portion SBP1 and overlapping the second light-emitting pixel driver EPD2 and the fourth light-emitting pixel driver EPD4.

The first sub-extension portion SBP1 may be disposed between the first light-emitting pixel driver EPD1 and the second light-emitting pixel driver EPD2 and between the third light-emitting pixel driver EPD3 and the fourth light-emitting pixel driver EPD4.

The second signal transmission line STRL2 which transmits the second signal may be the second emission control line ECL2 which transmits the second emission control signal EC2 (refer to FIG. 16).

The second signal transmission line STRL2 may include a second main portion MNP2 overlapping the second light-emitting pixel driver EPD2 and the fourth light-emitting pixel driver EPD4 and extending in the first direction DR1, a third sub-extension portion SBP3 electrically connected to the second main portion MNP2 and extending in the second direction DR2, and a fourth sub-extension portion SBP4 electrically connected to the third sub-extension portion SBP3 and overlapping the first light-emitting pixel driver EPD1 and the third light-emitting pixel driver EPD3.

The third sub-extension portion SBP3 may overlap all of the first light-emitting pixel driver EPD1, the second light-emitting pixel driver EPD2, the third light-emitting pixel driver EPD3, and the fourth light-emitting pixel driver EPD4.

The constant voltage transmission line CVTL which transmits the constant voltage may be the anode initialization voltage line VAIL which transmits the anode initialization voltage VAINT (refer to FIG. 16).

In an embodiment, the first signal transmission line STRL1, the second signal transmission line STRL2, and the constant voltage transmission line CVTL may be disposed in different conductive layers.

That is, the first signal transmission line STRL1 may be disposed in a second gate conductive layer GCDL2.

The second signal transmission line STRL2 may be disposed in a first gate conductive layer GCDL1.

The constant voltage transmission line CVTL may be disposed in a first source-drain conductive layer SDCDL1.

In an embodiment, a part of the first main portion MNP1 may overlap or be next (e.g., adjacent) to the fourth sub-extension portion SBP4, and a part of the second sub-extension portion SBP2 may overlap or be next (e.g., adjacent) to the second main portion MNP2.

Therefore, the constant voltage transmission line CVTL may overlap a part of the first main portion MNP1 and a part of the second sub-extension portion SBP2.

In this case, the coupling failure between the first signal and the second signal may be reduced.

In addition, the circuit layer 120 may further include a shielding protruding portion SPRP protruding from the constant voltage transmission line CVTL in the second direction DR2 and overlapping the third sub-extension portion SBP3.

In this case, the coupling failure between the first signal and the second signal may be further reduced.

In an embodiment, the fourth transistor T4 may be disposed in an area where the scan initialization line GIL and a semiconductor layer intersect.

The fifth transistor T5 may be disposed in an area where the first emission control line ECL1 and a semiconductor layer intersect.

The sixth transistor T6 may be disposed in an area where the second emission control line ECL2 and a semiconductor layer intersect or are next (e.g., adjacent) to each other.

A display device in embodiments includes a circuit layer and an element layer disposed on a substrate.

The element layer may include light-emitting elements disposed in emission areas, respectively.

The circuit layer may include light-emitting pixel drivers electrically connected to the light-emitting elements of the element layer, respectively, and arranged side by side in a first direction and a second direction intersecting each other and a first signal transmission line transmitting a first signal to a first light-emitting pixel driver and a second light-emitting pixel driver, which neighbor each other in the second direction, among the light-emitting pixel drivers.

In addition, the circuit layer may further include a constant voltage transmission line transmitting a constant voltage to the first light-emitting pixel driver and the second light-emitting pixel driver.

The constant voltage transmission line may be disposed next (e.g., adjacent) to a boundary between the first light-emitting pixel driver and the second light-emitting pixel driver and may extend in the first direction.

A first sub-extension portion of the first signal transmission line which intersects the constant voltage transmission line may be disposed in a different conductive layer from the constant voltage transmission line.

That is, in embodiments, the first signal transmission line may include a first main portion overlapping the first light-emitting pixel driver and extending in the first direction, the first sub-extension portion electrically connected to the first main portion and extending in the second direction toward the second light-emitting pixel driver, and a second sub-extension portion electrically connected to the first sub-extension portion and overlapping the second light-emitting pixel driver.

The first sub-extension portion extending in the second direction may intersect the constant voltage transmission line disposed next (e.g., adjacent) to the boundary between the first light-emitting pixel driver and the second light-emitting pixel driver. Accordingly, for insulation between the first signal transmission line and the constant voltage transmission line, the first sub-extension portion may be disposed in a different conductive layer from the constant voltage transmission line.

In an embodiment, the constant voltage transmission line may be disposed in one of a first gate conductive layer and a second gate conductive layer, and the first sub-extension portion may be disposed in the other (i.e., a remaining one) of the first gate conductive layer and the second gate conductive layer.

In an alternative embodiment, the constant voltage transmission line may be disposed in the second gate conductive layer, and the first sub-extension portion may be disposed in one of the first gate conductive layer and a third gate conductive layer.

In this case, the number of first signal transmission lines disposed in a display area may be reduced to half of the number of pixel rows, each composed of light-emitting pixel drivers arranged side by side in the first direction. This may be advantageous for making the display device have relatively high resolution.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate comprising a display area in which emission areas are arranged;
a circuit layer disposed on the substrate, the circuit layer comprising:
light-emitting pixel drivers arranged side by side in a first direction and a second direction intersecting each other; and
a first signal transmission line which transmits a first signal to a first light-emitting pixel driver and a second light-emitting pixel driver, which neighbor each other in the second direction, among the light-emitting pixel drivers, the first signal transmission line comprising:
a first main portion overlapping the first light-emitting pixel driver and extending in the first direction;
a first sub-extension portion electrically connected to the first main portion and extending in the second direction; and
a second sub-extension portion electrically connected to the first sub-extension portion, extending in the first direction, and overlapping the second light-emitting pixel driver; and
an element layer disposed on the circuit layer and comprising:
light-emitting elements disposed in the emission areas, respectively, and electrically connected to the light-emitting pixel drivers, respectively.

2. The display device of claim 1, wherein the circuit layer further comprises a constant voltage transmission line which transmits a constant voltage to the first light-emitting pixel driver and the second light-emitting pixel driver, and
wherein the constant voltage transmission line is disposed next to a boundary between the first light-emitting pixel driver and the second light-emitting pixel driver and extends in the first direction, and the first sub-extension portion intersects the constant voltage transmission line.

3. The display device of claim 2, wherein the circuit layer further comprises second signal transmission lines which extends in the first direction and transmits a second signal to the first light-emitting pixel driver and the second light-emitting pixel driver, and
wherein one of the second signal transmission lines overlaps the first light-emitting pixel driver, and a remaining one of the second signal transmission lines overlaps the second light-emitting pixel driver.

4. The display device of claim 3, wherein the one of the second signal transmission lines is disposed between the first main portion and the constant voltage transmission line in the second direction, the remaining one of the second signal transmission lines is disposed between the second sub-extension portion and the constant voltage transmission line in the second direction, and the circuit layer further comprises a shielding protruding portion protruding from the constant voltage transmission line in the second direction and overlapping intersection areas of the first sub-extension portion and the second signal transmission lines.

5. The display device of claim 3, wherein each of the light-emitting pixel drivers comprises:
a first transistor electrically connected between a first node and a second node;
a pixel capacitor electrically connected between a first power line, which transmits first power, and a third node;
a second transistor electrically connected between a data line, which transmits a data signal, and the first node;
a third transistor electrically connected between the second node and the third node; and
a fourth transistor electrically connected between a gate initialization voltage line, which transmits a gate initialization voltage, and the third node, and
wherein the first node is electrically connected to a first electrode of the first transistor, the second node is electrically connected to a second electrode of the first transistor, the third node is electrically connected to a gate electrode of the first transistor, the third transistor is turned on by a scan initialization signal of a scan initialization line, the fourth transistor is turned on by a gate control signal of a gate control line, one of the first signal transmission line and the second signal transmission lines is the scan initialization line, the remaining one is the gate control line, and the constant voltage transmission line is the gate initialization voltage line.

6. The display device of claim 2, wherein the light-emitting pixel drivers further comprise a third light-emitting pixel driver neighboring the first light-emitting pixel driver in the first direction and a fourth light-emitting pixel driver neighboring the second light-emitting pixel driver in the first direction, the first signal transmission line and the constant voltage transmission line are electrically connected to the third light-emitting pixel driver and the fourth light-emitting pixel driver, the first main portion further overlaps the third light-emitting pixel driver, the second sub-extension portion further overlaps the fourth light-emitting pixel driver, and the circuit layer further comprises a second signal transmission line which transmits a second signal to the first light-emitting pixel driver, the second light-emitting pixel driver, the third light-emitting pixel driver and the fourth light-emitting pixel driver,
wherein the second signal transmission line comprises:
a second main portion overlapping the second light-emitting pixel driver and the fourth light-emitting pixel driver and extending in the first direction;
a third sub-extension portion electrically connected to the second main portion and extending in the second direction; and
a fourth sub-extension portion electrically connected to the third sub-extension portion, extending in the first direction, and overlapping the first light-emitting pixel driver and the third light-emitting pixel driver, and
wherein the first main portion is disposed between the constant voltage transmission line and the fourth sub-extension portion, and the second sub-extension portion is disposed between the constant voltage transmission line and the second main portion.

7. The display device of claim 6, wherein the circuit layer further comprises a shielding protruding portion protruding from the constant voltage transmission line in the second direction and overlapping an intersection area of the third sub-extension portion and the first main portion.

8. The display device of claim 6, wherein each of the light-emitting pixel drivers comprises:
a first transistor electrically connected between a first node and a second node;
a pixel capacitor electrically connected between a first power line, which transmits first power, and a third node;
a second transistor electrically connected between a data line, which transmits a data signal, and the first node;
a third transistor electrically connected between the second node and the third node; and
a fourth transistor electrically connected between a gate initialization voltage line, which transmits a gate initialization voltage, and the third node, and
wherein the first node is electrically connected to a first electrode of the first transistor, the second node is electrically connected to a second electrode of the first transistor, the third node is electrically connected to a gate electrode of the first transistor, the third transistor is turned on by a scan initialization signal of a scan initialization line, the fourth transistor is turned on by a gate control signal of a gate control line, the first signal transmission line is the scan initialization line, the second signal transmission line is the gate control line, and the constant voltage transmission line is the gate initialization voltage line.

9. The display device of claim 6, wherein each of the light-emitting pixel drivers comprises:
a first transistor electrically connected between a first node and a second node;
a second transistor electrically connected between a data line, which transmits a data signal, and a third node;
a third transistor electrically connected between a reference voltage line, which transmits a gate reference voltage, and the third node;
a first pixel capacitor electrically connected between the second node and the third node;
a second pixel capacitor electrically connected between a first power line, which transmits first power, and the second node;
a fourth transistor electrically connected between an anode initialization voltage line, which transmits an anode initialization voltage, and a fourth node;
a fifth transistor electrically connected between the first power line and the first node; and
a sixth transistor electrically connected between the second node and the fourth node, and
wherein the first node is electrically connected to a first electrode of the first transistor, the second node is electrically connected to a second electrode of the first transistor, the third node is electrically connected to a gate electrode of the first transistor, the fourth node is electrically connected to one of the light-emitting elements, the fourth transistor is turned on by a scan initialization signal of a scan initialization line, the fifth transistor is turned on by a first emission control signal of a first emission control line, the sixth transistor is turned on by a second emission control signal of a second emission control line, the first signal transmission line is the scan initialization line, the second signal transmission line is the second emission control line, and the constant voltage transmission line is the anode initialization voltage line.

10. The display device of claim 2, wherein the circuit layer comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first inter-insulating layer covering the second gate conductive layer;
a second semiconductor layer disposed on the first inter-insulating layer;
a third gate insulating layer covering the second semiconductor layer;
a third gate conductive layer disposed on the third gate insulating layer; and
a second inter-insulating layer covering the third gate conductive layer.

11. The display device of claim 10, wherein the constant voltage transmission line is disposed in one of the first gate conductive layer and the second gate conductive layer, the first sub-extension portion is disposed in a remaining one of the first gate conductive layer and the second gate conductive layer, and the first main portion and the second sub-extension portion are disposed in the third gate conductive layer.

12. The display device of claim 11, wherein the constant voltage transmission line is disposed in the second gate conductive layer, the first sub-extension portion is disposed in one of the first gate conductive layer and the third gate conductive layer, and the first main portion and the second sub-extension portion are disposed in the third gate conductive layer.

13. The display device of claim 11, wherein the circuit layer further comprises a first source-drain conductive layer disposed on the second inter-insulating layer, and
wherein the constant voltage transmission line is disposed in the first source-drain conductive layer, the first signal transmission line is disposed in one of the first gate conductive layer and the second gate conductive layer, and the second signal transmission line is disposed in the remaining one of the first gate conductive layer and the second gate conductive layer.

14. An electronic device comprising a display device as a display screen,
wherein the display device comprises:
a substrate comprising a display area in which emission areas are arranged;
a circuit layer disposed on the substrate, the circuit layer comprising:
light-emitting pixel drivers arranged side by side in a first direction and a second direction intersecting each other;
a first signal transmission line which transmits a first signal to a first light-emitting pixel driver and a second light-emitting pixel driver, which neighbor each other in the second direction, among the light-emitting pixel drivers, the first signal transmission line comprising:
a first sub-extension portion; and
a constant voltage transmission line which transmits a constant voltage to the first light-emitting pixel driver and the second light-emitting pixel driver, is next to a boundary between the first light-emitting pixel driver and the second light-emitting pixel driver and extends in the first direction; and
an element layer disposed on the circuit layer and comprising:
light-emitting elements disposed in the emission areas, respectively, and electrically connected to the light-emitting pixel drivers, respectively,
wherein the first sub-extension portion intersects the constant voltage transmission line, and is disposed in a different conductive layer from the constant voltage transmission line.

15. The electronic device of claim 14, wherein the circuit layer comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first inter-insulating layer covering the second gate conductive layer;
a second semiconductor layer disposed on the first inter-insulating layer;
a third gate insulating layer covering the second semiconductor layer;
a third gate conductive layer disposed on the third gate insulating layer; and
a second inter-insulating layer covering the third gate conductive layer.

16. The electronic device of claim 15, wherein the constant voltage transmission line is disposed in one of the first gate conductive layer and the second gate conductive layer, and the first sub-extension portion is disposed in a remaining one of the first gate conductive layer and the second gate conductive layer.

17. The electronic device of claim 15, wherein the constant voltage transmission line is disposed in the second gate conductive layer, and the first sub-extension portion is disposed in one of the first gate conductive layer and the third gate conductive layer.

18. The electronic device of claim 15, wherein the light-emitting pixel drivers further comprise a third light-emitting pixel driver neighboring the first light-emitting pixel driver in the first direction and a fourth light-emitting pixel driver neighboring the second light-emitting pixel driver in the first direction, the first signal transmission line and the constant voltage transmission line are electrically connected to the third light-emitting pixel driver and the fourth light-emitting pixel driver, and the circuit layer further comprises a second signal transmission line which transmits a second signal to the first light-emitting pixel driver, the second light-emitting pixel driver, the third light-emitting pixel driver and the fourth light-emitting pixel driver and a first source-drain conductive layer disposed on the second inter-insulating layer, and
wherein the constant voltage transmission line is disposed in the first source-drain conductive layer, the first signal transmission line is disposed in one of the first gate conductive layer and the second gate conductive layer, and the second signal transmission line is disposed in the remaining one of the first gate conductive layer and the second gate conductive layer.

19. The electronic device of claim 15, wherein the light-emitting pixel drivers further comprise a third light-emitting pixel driver neighboring the first light-emitting pixel driver in the first direction and a fourth light-emitting pixel driver neighboring the second light-emitting pixel driver in the first direction, the first signal transmission line and the constant voltage transmission line are electrically connected to the third light-emitting pixel driver and the fourth light-emitting pixel driver, and the circuit layer further comprises a second signal transmission line which transmits a second signal to the first light-emitting pixel driver, the second light-emitting pixel driver, the third light-emitting pixel driver and the fourth light-emitting pixel driver, and
wherein the first signal transmission line further comprises a first main portion overlapping the first light-emitting pixel driver and extending in the first direction and a second sub-extension portion overlapping the second light-emitting pixel driver, the first sub-extension portion is electrically connected between the first main portion and the second sub-extension portion, the second signal transmission line comprises a third sub-extension portion intersecting the constant voltage transmission line and the first main portion, and the third sub-extension portion is disposed in a different conductive layer from the constant voltage transmission line and the first main portion.

20. The electronic device of claim 19, wherein the circuit layer further comprises a shielding protruding portion protruding from the constant voltage transmission line in the second direction and overlapping an intersection area of the third sub-extension portion and the first main portion.
